(19) United States
(12) Patent Application Publication
(10) Pub. No.: US 2025/0329589 A1
(43) Pub. Date: Oct. 23, 2025

(54) METHOD OF MANUFACTURING SEMICONDUCTOR DEVICE AND PRODUCT HISTORY MANAGEMENT METHOD FOR SEMICONDUCTOR DEVICE

(71) Applicant: Renesas Electronics Corporation, Tokyo (JP)

(72) Inventors: Tsuyoshi KANAO, Tokyo (JP); Junpei NONAKA, Tokyo (JP); Kenichi HISADA, Tokyo (JP)

(21) Appl. No.: 19/084,894

(22) Filed: Mar. 20, 2025

(30) Foreign Application Priority Data
Apr. 18, 2024 (JP) 2024-067613

(51) Int. Cl. H01L 21/66; H01L 21/324; H01L 23/544; H01L 23/58

(52) U.S. Cl. CPC H01L 22/12; H01L 21/324; H01L 23/544; H01L 23/585; H01L 2223/54433

(57) ABSTRACT

A technique that not only suppresses cost increase but also enables traceability of semiconductor devices with high accuracy is demanded. By mapping positions of crystal defects, position information of the crystal defects on a wafer map is stored in a memory device. In each of a plurality of chip areas, a metal film is formed in a wiring layer located above a semiconductor element. In each of the plurality of chip areas, a surface morphology image of a specific area of the metal film is acquired. The position information of the crystal defects on the wafer map, a wafer identification number, position information of the plurality of chip areas, position information of the specific area in the chip area, and the surface morphology image for each of the plurality of chip areas are linked and stored in a memory device.

### CROSS-REFERENCE TO RELATED APPLICATIONS

The disclosure of Japanese Patent Application No. 2024-067613 filed on Apr. 18, 2024 including the specification, drawings and abstract is incorporated herein by reference in its entirety.

### BACKGROUND

The present invention relates to a method of manufacturing a semiconductor device and a product history management method for semiconductor device.

When a defect is found after manufacturing of a semiconductor device, it is required to identify the cause of a defect at an early stage and provide feedback to a manufacturing step of the semiconductor device. For this purpose, traceability of semiconductor devices determined to be defective is effective. In other words, it is effective to identify which lot number and wafer identification number the semiconductor device determined to be defective belongs to, as well as the specific position within the wafer where the defective semiconductor device was manufactured.

There are disclosed techniques listed below.
Patent Document 1 Japanese Unexamined Patent Application Publication No. 2007-165389

For example, in Patent Document 1, images of dicing marks on the side surface of a wafer at the four corners of a semiconductor chip and images of contact marks on the surfaces of pad electrodes formed during probe testing are stored in a memory device. For an image of a semiconductor chip determined to be defective is similarly acquired, and by matching the image with the images stored in the memory device, the wafer identification number and the position within the wafer where the semiconductor chip determined to be defective was manufactured are identified.

### SUMMARY

Generally, e front-end process of semiconductor manufacturing, wafers are assigned identification marks. However, semiconductor chips diced from the wafer are not assigned identification marks. Assigning identification marks to all semiconductor chips enables traceability; however, such a method leads to increased costs.

The semiconductor chips diced from the wafer are packaged through the back-end process of the semiconductor to manufacturer a semiconductor device. Through the process, external connection members such as a bonding wire or a bump electrode is formed on the surface of the pad electrode. Also, the semiconductor chip is covered with a sealing resin. To ensure traceability of a semiconductor device determined to be defective, it is necessary to accurately acquire information that leads to the identification of the semiconductor chip even after the sealing resin is opened and the external connection members are removed.

In other words, there is a demand for a technique that not only suppresses cost increase but also enables traceability of semiconductor devices with high accuracy. There is also a demand for technique that can identify the cause of a defect in a semiconductor device at an early stage and provide feedback to the manufacturing method of the semiconductor device at an early stage. These techniques make it possible to supply highly reliable semiconductor devices after feedback, improve yield, and suppress the outflow of defective products to the market.

Other objects and novel features will become apparent from the description of the present specification and the accompanying drawings.

A brief outline of a representative embodiment of the present invention will be described below.

According to one embodiment, a method of manufacturing a semiconductor device includes (a) assigning a wafer identification number to a wafer made of silicon carbide, (b) partitioning the wafer into a plurality of chip areas arranged in a matrix and generating a wafer map, (c) inspecting the wafer for a crystal defect present therein, (d) storing position information of the crystal defect on the wafer map in a memory device by mapping a position of the crystal defect, (e) forming a semiconductor element in each of the plurality of chip areas, (f) forming a metal film in a wiring layer located above the semiconductor element in each of the plurality of chip areas, (g) acquiring a first surface morphology image of a specific area of the metal film in each of the plurality of chip areas, and (h) linking the position information of the crystal defect on the wafer map, the wafer identification number, position information of the plurality of chip areas, position information of the specific area in the chip area, and the first surface morphology image for each of the plurality of chip areas, and storing them in the memory device.

According to one embodiment, a product history management method for semiconductor device includes (a) assigning a wafer identification number to a wafer made of silicon carbide, (b) partitioning the wafer into a plurality of chip areas arranged in a matrix and generating a wafer map, (c) inspecting the wafer for a crystal defect present therein, (d) storing position information of the crystal defect on the wafer map in a memory device by mapping a position of the crystal defect, (e) forming a semiconductor element in each of the plurality of chip areas, (f) forming a metal film in a wiring layer located above the semiconductor element in each of the plurality of chip areas, (g) acquiring a first surface morphology image of a specific area of the metal film in each of the plurality of chip areas, (h) linking the wafer identification number, the position information of the crystal defect on the wafer map, position information of the plurality of chip areas, position information of the specific area in the chip area, and the first surface morphology image for each of the plurality of chip areas, and storing them in the memory device, (i) obtaining a plurality of semiconductor chips by dicing the plurality of chip areas of the wafer, (j) forming a plurality of first semiconductor devices by sealing the plurality of semiconductor chips with a sealing resin, (k) obtaining a second semiconductor device determined to be defective, (l) opening the sealing resin of the second semiconductor device and acquiring a second surface morphology image of a portion of the metal film provided on the second semiconductor device that corresponds to the specific area, and (m) identifying the wafer identification number of the wafer on which the second semiconductor device is manufactured and a position of the chip area on which the second semiconductor device is manufactured by matching the second surface morphology image with the first surface morphology image for each of the plurality of chip areas stored in the memory device. The position of the chip area identified in the (m) is matched with the position information of the crystal defect on the wafer map, and if the crystal defect is present in the chip area identified in the (m), it can be expected that a defect in the second semiconductor device is caused by the crystal defect.

According to one embodiment, not only cost increase is suppressed but also traceability of semiconductor devices can be performed with high accuracy. Further, the cause of a defect in a semiconductor device can be identified at an early stage and feedback to the manufacturing method of the semiconductor device can be performed at an early stage.

### BRIEF DESCRIPTION OF THE DRAWINGS

FIG. 1 is a flowchart illustrating a method of manufacturing a semiconductor device and a product history management method for semiconductor device in a first embodiment.

FIG. 2 is a plan view illustrating a wafer map in the first embodiment.

FIG. 3 is a plan view illustrating a chip area in the first embodiment.

FIG. 4 is a schematic diagram illustrating how data is stored in a memory device in the first embodiment.

FIG. 5 is a cross-sectional view illustrating a manufacturing step of the semiconductor device in the first embodiment.

FIG. 6 is a cross-sectional view illustrating a manufacturing step following FIG. 5.

FIG. 7 is a cross-sectional view illustrating a manufacturing step following FIG. 6.

FIG. 8 is a cross-sectional view illustrating a manufacturing step following FIG. 7.

FIG. 9 is a cross-sectional view illustrating a manufacturing step following FIG. 8.

FIG. 10 is a cross-sectional view illustrating a manufacturing step following FIG. 9.

FIG. 11 is a cross-sectional view illustrating a manufacturing step following FIG. 10.

FIG. 12 is a schematic diagram illustrating a manufacturing step following FIG. 11 and a subsequent product history management step for the semiconductor device.

FIG. 13 is a plan view illustrating a product history management step following FIG. 12.

FIG. 14 is a plan view illustrating position information of crystal defects in a second embodiment.

FIG. 15 is a schematic diagram illustrating a matching method of surface morphology images in a third embodiment.

FIG. 16 is a plan view illustrating a shape pattern of a metal film in a fourth embodiment.

FIG. 17 is a plan view illustrating a chip area in a fifth embodiment.

FIG. 18 is a flowchart illustrating a method of manufacturing a semiconductor device and a product history management method for semiconductor device in a sixth embodiment.

FIG. 19 is a schematic diagram illustrating how data is stored in a memory device in the sixth embodiment.

FIG. 20 is a plan view illustrating a product history management method for semiconductor device in the sixth embodiment.

### DETAILED DESCRIPTION

Hereinafter, embodiments will be described in detail with reference to the drawings. In all the drawings for explaining the embodiments, the same reference numerals are given to members having the same functions, and the repeated descriptions are omitted. Further, in the following embodiments, descriptions of identical or similar parts will not be repeated in principle unless particularly necessary.

Also, an X direction, a Y direction, and a Z direction described in the present application intersect with each other and are perpendicular to each other. In the present application, the Z direction will be described as the vertical direction, the height direction, or the thickness direction of a structure. Further, representation such as “plan view” or “planar view” used in the present application means that a surface defined by the X direction and the Y direction is a “plane” and that the “plane” is viewed from the Z direction.

### First Embodiment

### <Method of Manufacturing Semiconductor Device and Product History Management Method for Semiconductor Device>

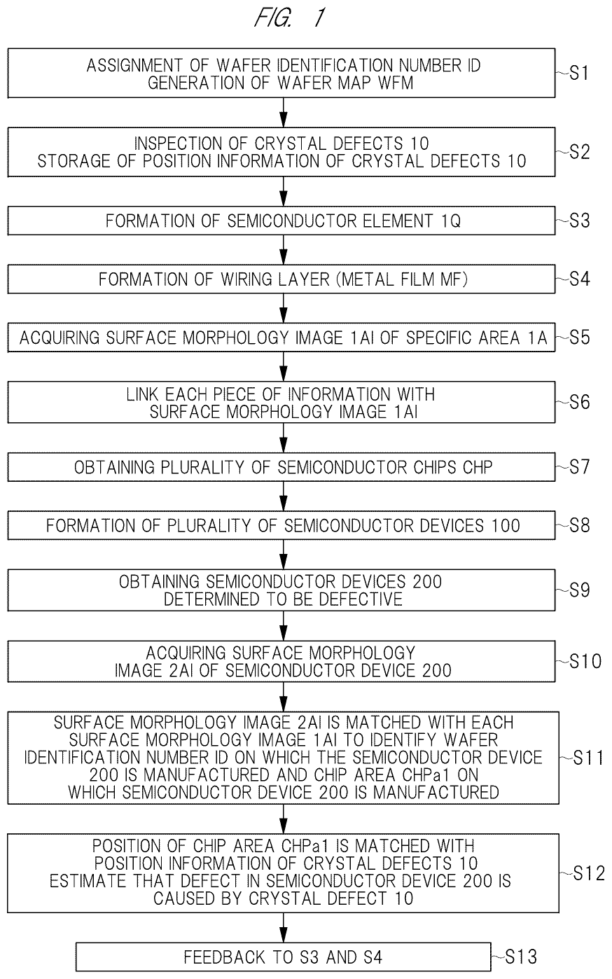

A method of manufacturing semiconductor device 100 and a product history management method for semiconductor device 100 according to a first embodiment will be described below with reference to FIG. 1. The product history management method for semiconductor device 100 includes Step S1 to Step S13 illustrated in FIG. 1. The method of manufacturing the semiconductor device 100 is part of the product history management method for semiconductor device 100 and includes Step S1 to Step S8.

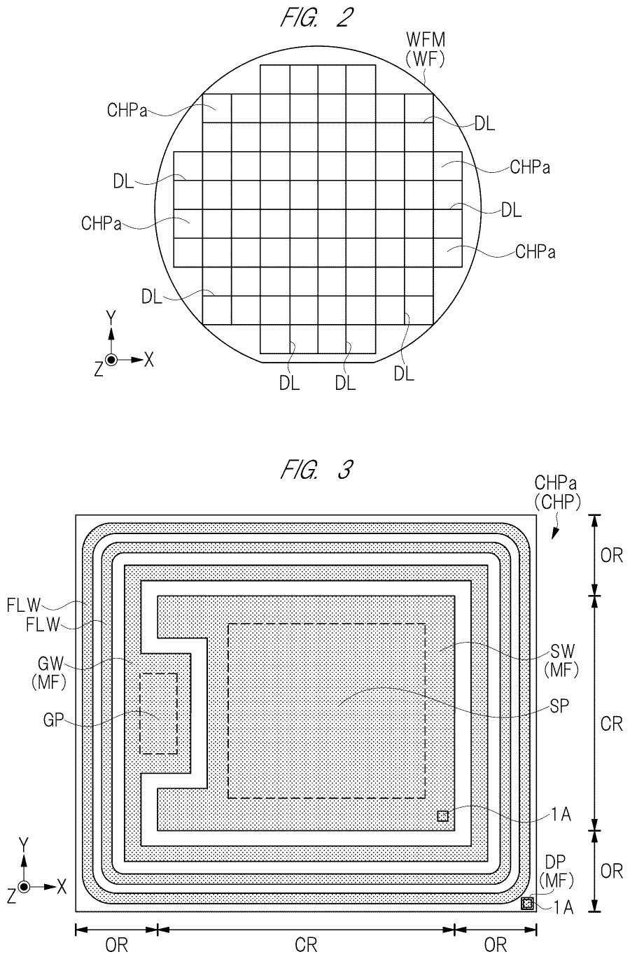

Also, in the description of Step S1 to Step S13, FIGS. 2 to 13 will be referred to as needed.

In Step S1, first, a wafer WF is prepared, and a wafer identification number ID is assigned to a part of the wafer WF as illustrated in FIG. 4. Next, as illustrated in FIG. 2, the wafer WF is partitioned into a plurality of chip areas CHPa arranged in a matrix, and a wafer map WFM is generated. The plurality of chip areas CHPa is each partitioned by dicing lines DL. The plurality of chip area CHPa is diced along the dicing lines DL to obtain a plurality of semiconductor chips CHP.

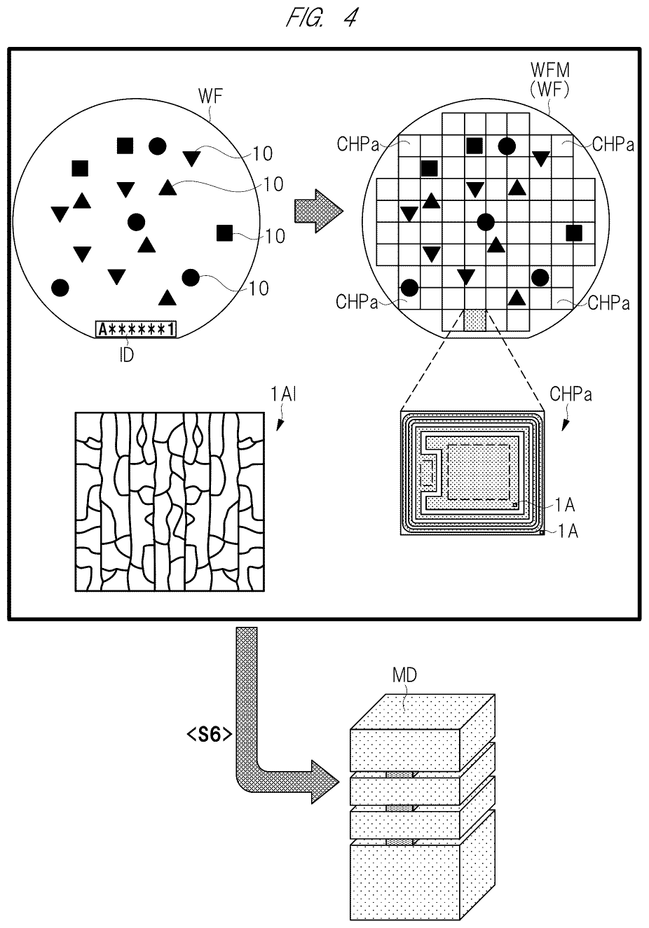

FIG. 3 is a plan view illustrating the details of a chip area CHPa (semiconductor chip CHP). The chip area CHPa has a cell region CR in which a semiconductor element 10 is formed, and an outer periphery region OR surrounding the cell region CR in plan view. The semiconductor element 10 is a power device such as a power metal oxide semiconductor field effect transistor (MOSFET) or an insulated gate bipolar transistor (IGBT). In the first embodiment, a case is illustrated as an example where the semiconductor element 10 is an n-type power MOSFET with a trench gate structure.

A source wiring SW is formed in a large part of the cell region CR. A gate wiring GW is formed in the outer periphery region OR so as to surround the source wiring SW in plan view. A field limiting wiring FLW is formed in the outer periphery region OR so as to surround the gate wiring GW in plan view. The source wiring SW and the gate wiring GW are formed from a same metal film MF and are electrically connected to the semiconductor element 1Q.

Also, in the outer periphery region OR, a dummy pattern DP is formed between the field limiting wiring FLW and the dicing line DL (the side surface of the semiconductor chip CHP). The dummy pattern DP is formed from the metal film MF and is electrically insulated from the semiconductor element 10.

Although not illustrated here, the source wiring SW, the gate wiring GW, the field limiting wiring FLW and the dummy pattern DP are covered with a protective film PIQ such as a polyimide film. Openings are provided in a part of the protective film PIQ. The portions of the source wiring SW and the gate wiring GW exposed in the opening become a source pad SP and a gate pad GP. The areas surrounded by dashed lines in FIG. 3 are the source pad SP and the gate pad GP. By connecting external connection members such as bonding wires, bump electrodes or clips (copper plates) to the source pad SP and the gate pad GP, the semiconductor chip CHP can be electrically connected to another semiconductor chip or a wiring board.

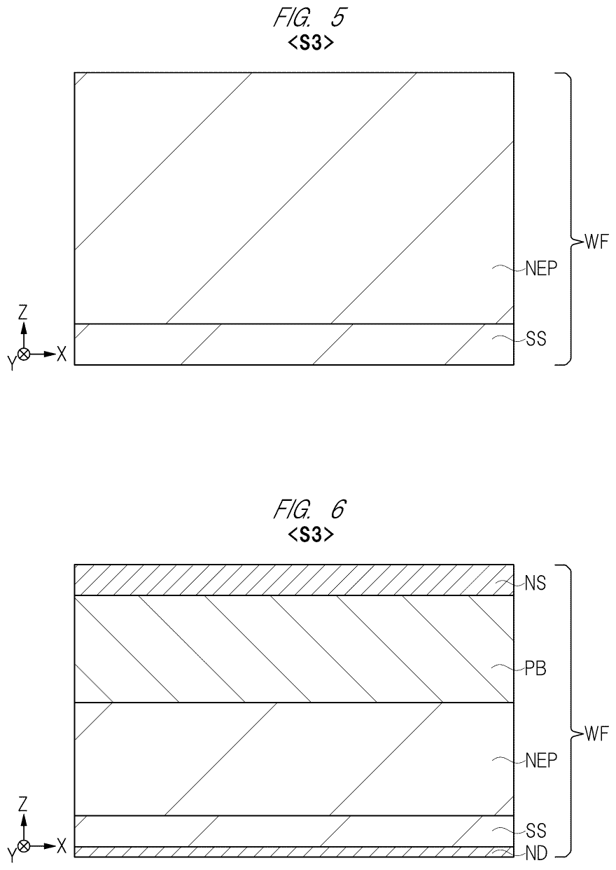

The wafer WF is made of silicon carbide (Sic) and has n-type conductivity. As illustrated in FIG. 5, the wafer WF has a support substrate SS made of silicon carbide and a semiconductor layer NEP made of silicon carbide. The semiconductor layer NEP is formed on the support substrate SS by epitaxial growth. The support substrate SS and the semiconductor layer NEP have n-type conductivity. The semiconductor layer NEP has an impurity concentration lower than the impurity concentration of the support substrate SS, and functions as a drift layer.

It is known that various crystal defects are present in the support substrate SS made of silicon carbide. Also, it is highly possible that various crystal defects are also present in the semiconductor layer NEP, since crystalline defects propagate during epitaxial growth. Therefore, the wafer WF made of silicon carbide tends to have a higher frequency of defects caused by crystalline defects compared to wafers made of silicon.

In Step S2, as illustrated in FIG. 4, first, crystal defects 10 present in the wafer WF are inspected. Next, by mapping the positions of the crystal defects 10, position information of the crystal defects 10 on the wafer map WFM is stored in a memory device MD.

As for the types of crystalline defects, examples include basal plane defects, stacking faults, screw dislocations, and micropipes. The semiconductor element 10 and the like are formed in the subsequent steps, the semiconductor device 100 may later be determined to be defective. At this point, it is difficult to determine which types of crystal defect 10 are directly linked to a failure, or not. Depending on the types of semiconductor element 1Q, manufacturing conditions in each manufacturing step for manufacturing the semiconductor element 10, or usage conditions of the semiconductor device 100, any one of the crystal defects 10 may become a cause of a defect. Therefore, the position information of the crystal defects 10 on the wafer map WFM is acquired in order to identify or estimate which types of crystal defect 10 caused the defect.

In Step S3, the semiconductor element 10 is formed in each of the plurality of chip areas CHPa. Each manufacturing step for forming the semiconductor element 10 will be described below with reference to FIGS. 5 to 9.

As illustrated in FIG. 5, a wafer WF is prepared. As described above, the wafer WF has the support substrate SS and the semiconductor layer NEP formed on the support substrate SS by epitaxial growth.

As illustrated in FIG. 6, an n-type drain region ND, a p-type body region PB, and an n-type source region NS are formed in the wafer WF.

First, the drain region ND is formed in the support substrate SS by photolithography and ion implantation so as to reach a predetermined depth from the lower surface of the wafer WF. Next, the body region PB is formed in the semiconductor layer NEP by photolithography and ion implantation so as to reach a predetermined depth from the upper surface of the wafer WF. Next, the source region NS is formed in the body region PB by photolithography and ion implantation so as to reach a predetermined depth from the upper surface of the wafer WF. The drain region ND and the source region NS each have an impurity concentration higher than the impurity concentration of the semiconductor layer NEP.

As illustrated in FIG. 7, a trench TR is formed in the semiconductor layer NEP so as to reach a predetermined depth from the upper surface of the wafer WF.

First, for example, a silicon oxide film is formed on the wafer WF by a film forming process using, for example, a chemical vapor deposition (CVD) method. Next, the silicon oxide film is patterned by photolithography and anisotropic etching to form a hard mask. Next, by performing anisotropic etching using the hard mask as a mask, a trench TR is formed so as to penetrate the source region NS and body region PB, and extend into the semiconductor layer NEP. Thereafter, the hard mask is removed by isotropic etching using a solution containing, for example, hydrofluoric acid.

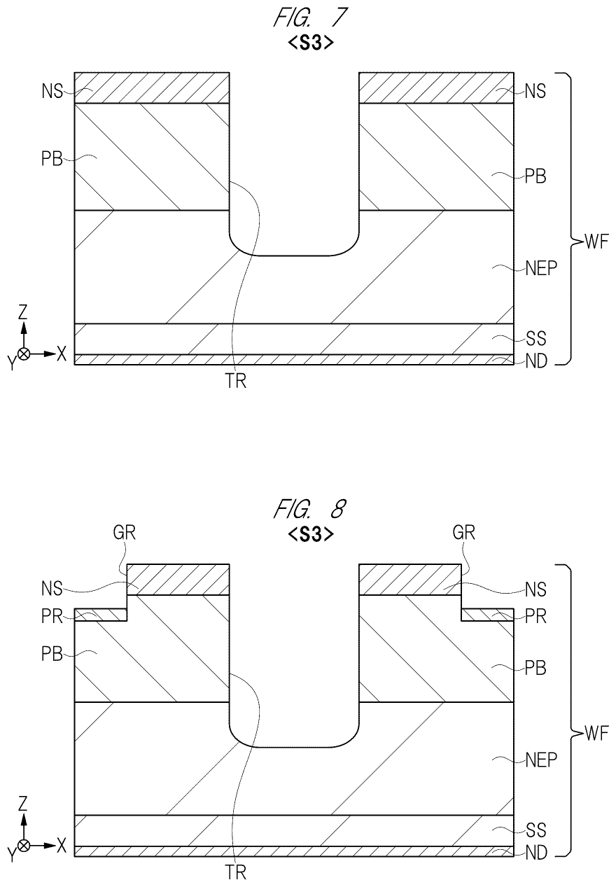

As illustrated in FIG. 8, a groove GR is formed in the semiconductor layer NEP so as to reach a predetermined depth from the upper surface of the wafer WF, and a high concentration diffusion region PR is formed at the bottom of the groove GR.

First, a groove GR is selectively formed in the semiconductor layer NEP by photolithography and anisotropic etching. The groove GR penetrates the source region NS and extends into the body region PB. Next, a p-type high concentration diffusion region PR is formed in the body region PB at the bottom of the groove GR by photolithography and ion implantation. The high concentration diffusion region PR has an impurity concentration higher than the impurity concentration of the body region PB.

Thereafter, the heat treatment is performed on the wafer WF in order to activate the impurities contained in the body region PB, the source region NS, and the high concentration diffusion region PR.

As illustrated in FIG. 9, a gate insulating film GI and a gate electrode GE are formed inside the trench TR.

First, the gate insulating film GI is formed inside the trench TR and on the upper surface of the wafer WF by thermal oxidation treatment. The gate insulating film GI is, for example, a silicon oxide film. Next, a conductive film is formed on the gate insulating film GI by a film forming process using, for example, a CVD method. The conductive film is, for example, an n-type polycrystalline silicon film.

Next, the gate insulating film GI and the gate electrode GE are patterned by photolithography and anisotropic etching. At this point, the inside of the trench TR is filled with the gate electrode GE via the gate insulating film GI. Also, on the upper surface of the wafer WF, the source region NS and the high concentration diffusion region PR are exposed from the gate insulating film GI and the gate electrode GE.

As described above, the semiconductor element 10 is formed in each of the chip areas CHPa.

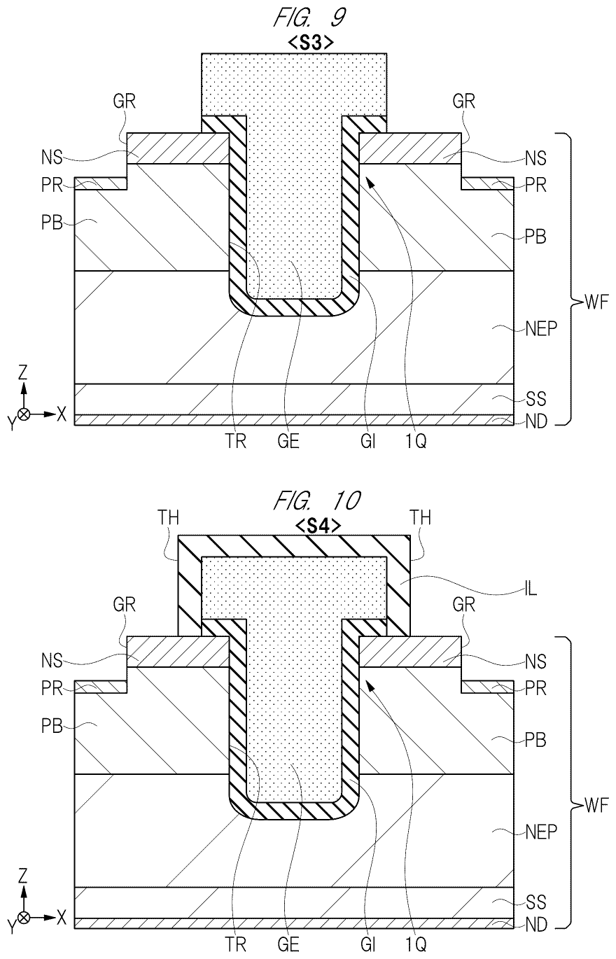

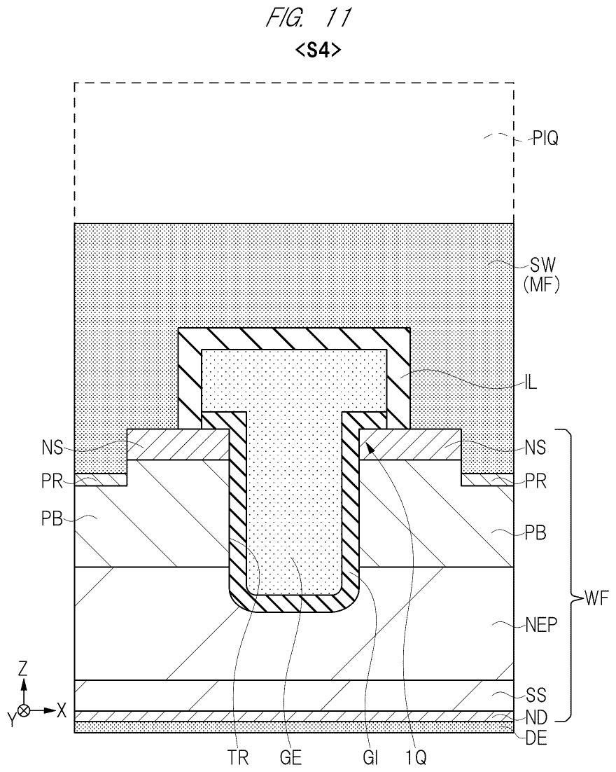

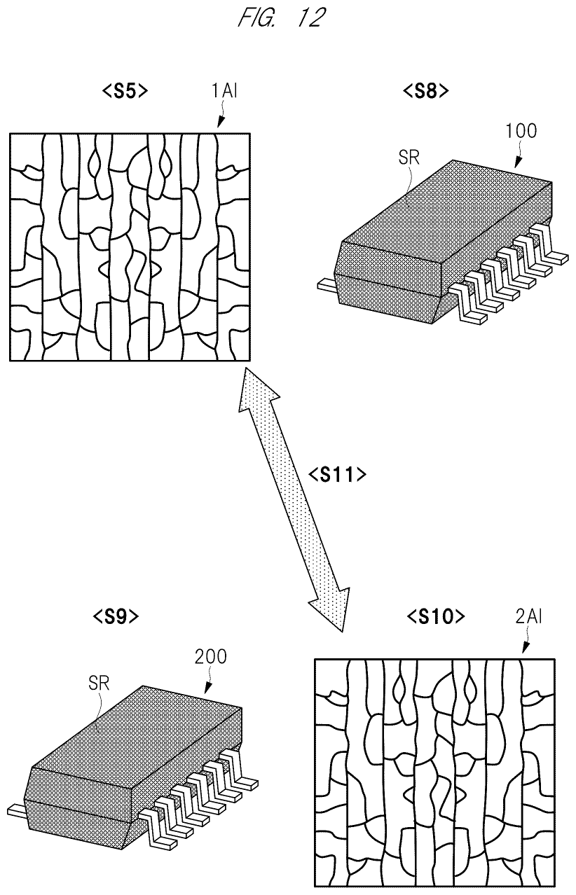

In Step S4, the metal film MF is formed in the wiring layer located above the semiconductor element 10 in each of the plurality of chip areas CHPa. Each manufacturing step for forming the wiring layer will be described below with reference to FIGS. 10 and 11.

As illustrated in FIG. 10, first, an interlayer insulating film IL is formed on the upper surface of the wafer WF by, for example, a CVD method so as to cover the gate electrode GE. Next, the interlayer insulating film IL is patterned by photolithography and anisotropic etching to form a through hole TH. At this point, the gate electrode GE is covered with the interlayer insulating film IL. Further, on the upper surface of the wafer WF, the source region NS and the high concentration diffusion region PR are exposed in the through hole TH.

As illustrated in FIG. 11, the metal film MF is formed on the interlayer insulating film IL and the upper surface of the wafer WF by a film forming process using a sputtering method or a CVD method so as to fill the through hole TH and the groove GR. The metal film MF is a film mainly made of aluminum. Specifically, the metal film MF is a laminated film including a barrier metal film made from, for example, a titanium tungsten film, and an aluminum alloy film formed on the barrier metal film and having, for example, copper or silicon added thereto.

Next, the metal film MF is patterned by photolithography and anisotropic etching. Accordingly, as illustrated in FIG. 3, the source wiring SW, the gate wiring GW, the field limiting wiring FLW, and the dummy pattern DP are formed from the metal film MF in a first wiring layer. In the first embodiment, a wiring layer located above the semiconductor element 10 is only the first wiring layer.

The source wiring SW is electrically connected to the source region NS, the high concentration diffusion region PR, and the body region PB, and supplies a source potential to these regions. Although not illustrated here, a through hole TH is also formed on the gate wiring GW. Therefore, the gate wiring GW is electrically connected to the gate electrode GE and supplies a gate potential to the gate electrode GE.

Alternatively, a plug layer mainly made from, for example, a tungsten film may be formed in the through hole TH and in the groove GR, and then the metal film MF may be formed on the interlayer insulating film IL. In this case, the source wiring SW is electrically connected to the source region NS, the high concentration diffusion region PR, and the body region PB via the plug layer. Further, the gate wiring GW and the gate electrode GE are electrically connected to each other via the plug layer.

Next, the protective film PIQ made from, for example, a polyimide film is formed on the source wiring SW, the gate wiring GW, the field limiting wiring FLW, and the dummy pattern DP by, for example, a coating method. Next, by exposing part of the protective film PIQ and forming openings, the regions that will become the source pad SP and gate pad GP of the source electrode SE and gate wiring GW are exposed. Next, a drain electrode DE is formed on the lower surface of the wafer WF by a film forming process using a sputtering method.

Processing histories included in the manufacturing process of the semiconductor element 10 in Step S3 and the manufacturing process of the metal film MF in Step S4 is stored in the memory device MD.

In Step S5, a surface morphology image 1AI of a specific area 1A of the metal film MF is acquired in each of the plurality of chip areas CHPa.

As illustrated in FIG. 3, a part of the metal film MF present in the chip area CHPa is provided as the specific area 1A. The position of the specific area 1A is the same for each of the plurality of chip areas CHPa. In the first embodiment, the metal film MF is formed so as to occupy the specific area 1A. In the example of FIG. 3, for example, a part of the source wiring SW or a part of the dummy pattern DP is used as the specific area 1A. For example, a part of the gate wiring GW may also be used as the specific area 1A. The planar size of the specific area 1A is, for example, 50 μm×50 μm or more and 200 μm×200 μm or less.

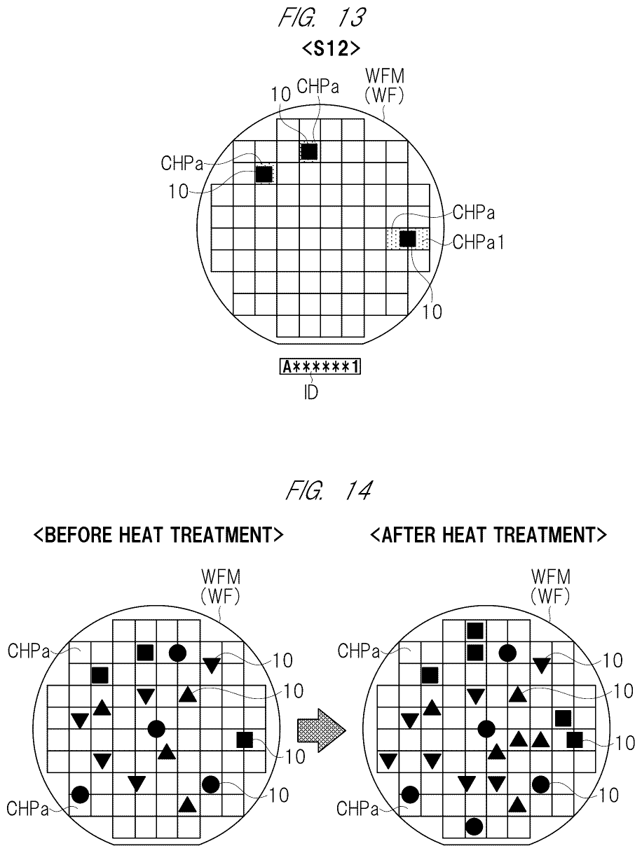

As illustrated in FIG. 12, a surface morphology image 1AI of the specific area 1A is acquired for each of the plurality of chip areas CHPa, and the surface morphology images 1AI are stored in the memory device MD.

In Step S5, it is preferable to acquire the surface morphology image 1AI via the protective film PIQ with the specific area 1A being covered with the protective film PIQ. The surface morphology image 1AI is used later to match with a surface morphology image 2AI of a semiconductor device 200 determined to be defective. For example, if the specific area 1A is set in the source pad SP, there is a risk that a bonding wire or the like will be provided in the specific area 1A. As a result, the surface morphology image 2AI of the semiconductor device 200 cannot be acquired.

Also, if the specific area 1A is not covered with the protective film PIQ when the surface morphology image 2AI is acquired, there is a risk that the surface condition of the specific area 1A of the semiconductor device 200 may change. As a result, it becomes difficult to acquire an accurate surface morphology image 2AI.

In Step S6, as illustrated in FIG. 4, the wafer identification number ID, the position information of the crystal defects 10 on the wafer map WFM, the position information of the plurality of chip areas CHPa, the position information of the specific area 1A in the chip area CHPa, and the surface morphology image 1AI for each of the plurality of chip areas CHPa are linked together and stored in the memory device MD. The surface morphology image 1AI thus linked to each piece of information can be effectively used for traceability of the semiconductor device 200 determined to be defective.

In Step S7, the plurality of chip areas CHPa of the wafer WF is diced along the dicing lines DL to obtain the plurality of semiconductor chips CHP.

In Step S8, a plurality of semiconductor devices 100 is formed by sealing the plurality of semiconductor chips CHP with a sealing resin SR, respectively.

For example, first, the semiconductor chip CHP is mounted on a lead frame, and the source pad SP, gate pad GP and the drain electrode DE are electrically connected to the lead terminals, respectively, using the external connection members such as bonding wires, clips or paste materials. Next, the semiconductor chip CHP and each lead terminal are sealed with the sealing resin SR such as epoxy resin. By cutting off each lead terminal from the lead frame, a semiconductor device 100 as illustrated in FIG. 12 is formed.

In this manner, the plurality of semiconductor devices 100 can be obtained from the wafer WF.

In Step S9, as illustrated in FIG. 12, the semiconductor device 200 determined to be defective is obtained. The semiconductor device 200 determined to be defective is, for example, a semiconductor device that has been shipped to a customer and then returned due to a defect in the semiconductor device pointed out by the customer. In order to perform traceability of such a semiconductor device 200, the sealing resin SR of the semiconductor device 200 is opened. Also, the external connection members of the semiconductor device 200 are removed as necessary.

In Step S10, a surface morphology image 2AI of a portion of the metal film MF provided on the semiconductor device 200 that corresponds to the specific area 1A is acquired. At this point, when the portion corresponding to the specific area 1A is covered with the protective film PIQ, the surface morphology image 2AI may be acquired with the protective film PIQ being remained, or the surface morphology image 2AI may be acquired after removing the protective film PIQ. Since the specific area 1A is protected by the protective film PIQ, the surface of the specific area 1A is maintained in good condition even after the sealing resin SR is opened. Therefore, a highly accurate surface morphology image 2AI can be acquired.

In Step S11, the surface morphology image 2AI is matched with the surface morphology images 1AI for each of the plurality of chip areas CHPa stored in the memory device MD to identify the wafer identification number ID of the wafer WF on which the semiconductor device 200 is manufactured and the position of the chip area CHPa1 on which the semiconductor device 200 is manufactured.

Note that if the surface morphology image 2AI does not match any of the surface morphology images 1AI for each of the plurality of chip areas CHPa stored in the memory device MD, the semiconductor device 200 can be identified as a counterfeit product.

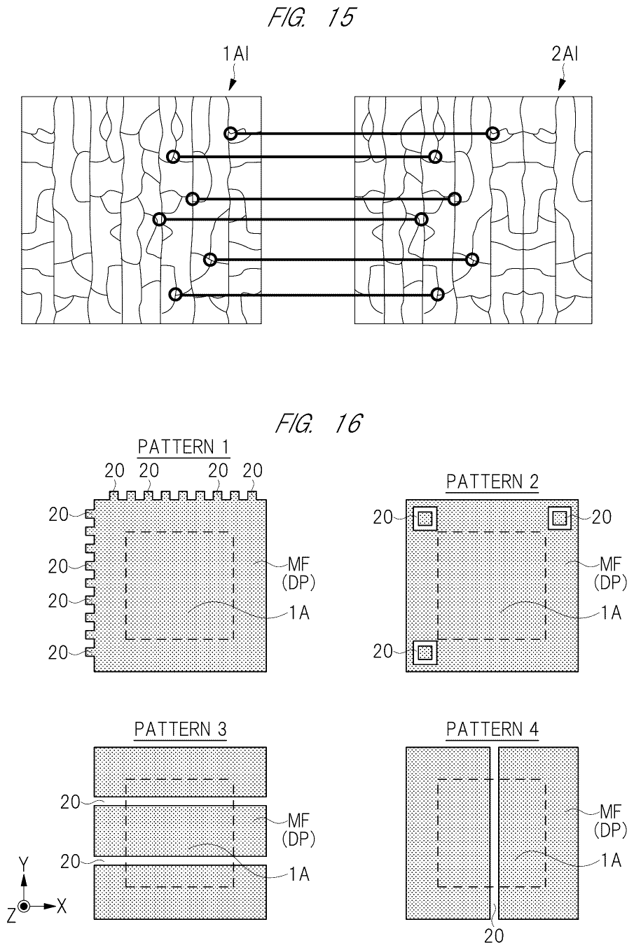

In Step S12, as illustrated in FIG. 13, the position of the identified chip area CHPa1 is matched with the position information of the crystal defects 10 on the wafer map WFM, and if a crystal defect 10 is present in the identified chip area CHPa1, it can be estimated that the defect in the semiconductor device 200 is caused by the crystal defect 10.

Also, the type of the crystal defect 10 present in the identified chip area CHPa1 has been determined in advance by the inspection in Step S2. Therefore, by matching with other chip areas CHPa on the wafer map WFM in which the same type of crystal defect 10 exists, it can be estimated that it is highly possible that the same defect as in the semiconductor device 200 will occur in the semiconductor devices 100 manufactured from the other chip areas CHPa.

In Step S13, the result of Step S12 is fed back to the manufacturing method of the semiconductor device 100. For example, the result of Step S12 can be fed back to Step S3 and Step S4 to review each manufacturing condition or measures such as not commercializing the chip area CHPa1 can be taken. Further, a similar measure may be taken for the chip area CHPa having the same type of crystal defect 10 as the chip area CHPa1.

Accordingly, according to the first embodiment, traceability can be performed without necessity of assigning an identification mark to every semiconductor chip CHP, and necessity of performing special processing in the wafer WF. Therefore, cost increase associated with traceability can be suppressed.

Further, even after the sealing resin SR is opened and the external connection members are removed, an accurate surface morphology image 2AI can be acquired. That is, information that leads to identification of the semiconductor chip CHP can be acquired with high accuracy. And, the cause of a defect in a semiconductor device 200 can be identified at an early stage and feedback to the manufacturing method of the semiconductor device 100 can be performed at an early stage. Accordingly, this makes it possible to supply highly reliable semiconductor devices 100 after feedback, improve yield, and suppress the outflow of defective products to the market.

In the first embodiment, the case has been illustrated as an example where the semiconductor element 10 is a power MOSFET, however, the semiconductor element 10 may be an IGBT. In this case, the source region NS, the source wiring SW, the body region PB, the drain region NS, and the drain electrode DE function as an emitter region, an emitter wiring, a base region, a collector region, and a collector electrode, respectively.

Further, in the first embodiment, the trench gate structure is adopted for the semiconductor element 10, however, the semiconductor element 10 may have a planar structure. In this case, no trench TR is formed inside the wafer WF, and the gate insulating film GI and the gate electrode GE are formed on the upper surface of the wafer WF.

### Second Embodiment

A method of manufacturing semiconductor device 100 and a product history management method for semiconductor device 100 according to a second embodiment will be described below with reference to FIG. 14. In the following description, differences from the first embodiment will be mainly described, and descriptions of points that overlap with the first embodiment will be omitted.

In the second embodiment, in addition to the position information (first position information) the crystal defects 10 stored in the memory device MD in Step S2, position information (second position information) the crystal defects 10 after the heat treatment is also acquired.

That is, after the heat treatment is performed on the wafer WF, the crystal defects 10 present in the wafer WF are re-inspected. Then, as illustrated in FIG. 14, by mapping the positions of the crystal defects 10 again, the position information (second position information) the crystal defects 10 on the wafer map WFM is stored in the memory device MD.

It is known that when the temperature of the heat treatment is high, the number of crystal defects 10 is likely to increase. Therefore, as illustrated in FIG. 14, the number of crystal defects 10 after the heat treatment changes from the number of crystal defects 10 before the heat treatment.

The position of the chip area CHPa1 specified in Step S11 is matched with both the first position information and the second position information. If the crystal defects 10 of the first position information are not present and the crystal defects 10 of the second position information are present in the identified chip area CHPa1, it can be estimated that the defect of the semiconductor device 200 is caused by the heat treatment.

In Step S12 the result that the defect is caused by the heat treatment is fed back to the manufacturing method of the semiconductor device 100. For example, the conditions of the heat treatment (temperature, time, etc.) can be changed so as not to increase the number of crystal defects 10.

Ideally, the method of the second embodiment is applied after all of the heat treatments performed in Step S3 and Step S4. However, to reduce the number of steps, the heat treatment targeted in the second embodiment may be limited only to the heat treatment that is expected to be more likely to increase the number of crystal defects 10, such as the heat treatment at a relatively high temperature. For example, the heat treatment targeted in second embodiment may be the heat treatment for activating impurities in FIG. 8 or the thermal oxidation treatment for forming the gate insulating film GI in FIG. 9.

### Third Embodiment

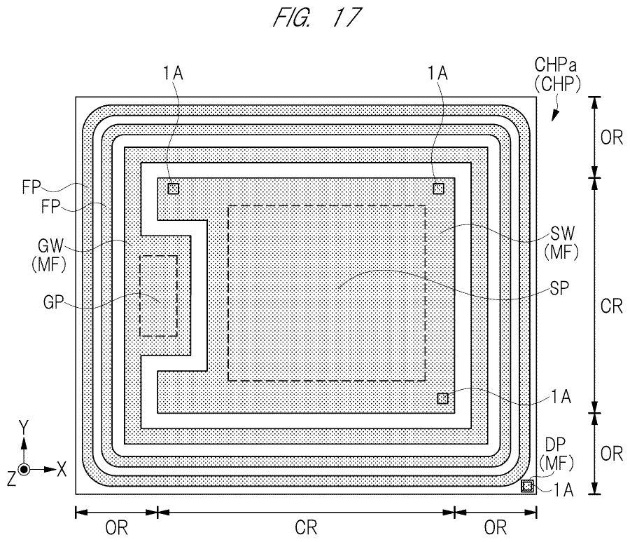

A method of manufacturing semiconductor device 100 and a product history management method for semiconductor device 100 according to a third embodiment will be described below with reference to FIG. 15. In the following description, differences from the first embodiment will be mainly described, and descriptions of points that overlap with the first embodiment will be omitted.

In the third embodiment, as illustrated in FIG. 15, the surface morphology image 1AI and the surface morphology image 2AI are matched using a plurality of feature amounts extracted from each image.

In Step S5, while the surface morphology image 1AI is acquired, the plurality of feature amounts of the surface morphology image 1AI is also extracted. For example, in the surface morphology image 1AI, an intersection point where a plurality of line segments meet, or a center of an area surrounded by line segments, is defined as a feature point, and a feature amount at the feature point is extracted.

In Step S6, the plurality of feature amounts is stored in the memory device MD as information related to the surface morphology image 1AI.

In Step S10, while the surface morphology image 2AI is acquired, a plurality of feature amounts of the surface morphology image 2AI is also extracted.

In Step S11, the surface morphology image 2AI is matched with the surface morphology image 1AI for each of the plurality of chip areas CHPa stored in the memory device MD by comparing the plurality of feature amounts of the surface morphology image 2AI with the plurality of feature amounts of the surface morphology image 1AI.

In the third embodiment, since the plurality of feature amounts are matched with each other, it is possible to determine whether the image is within the specific area 1A even if the coordinates of the surface morphology image 1AI and the coordinates of the surface morphology image 2AI do not completely match.

For example, there may be cases where the coordinates when capturing the surface morphology image 2AI are slightly shifted from the coordinates when capturing the surface morphology image 1AI, or where surface morphology image 2AI is captured in a rotated state relative to the surface morphology image 1AI. Even in such cases, if the plurality of feature amounts match each other, it can be determined that these images are within the specific area 1A. Therefore, by using the plurality of feature amounts of each other, the matching accuracy between the surface morphology image 1AI and the surface morphology image 2AI can be improved.

The technique disclosed in the third embodiment can be applied in combination with the technique disclosed in the second embodiment.

### Fourth Embodiment

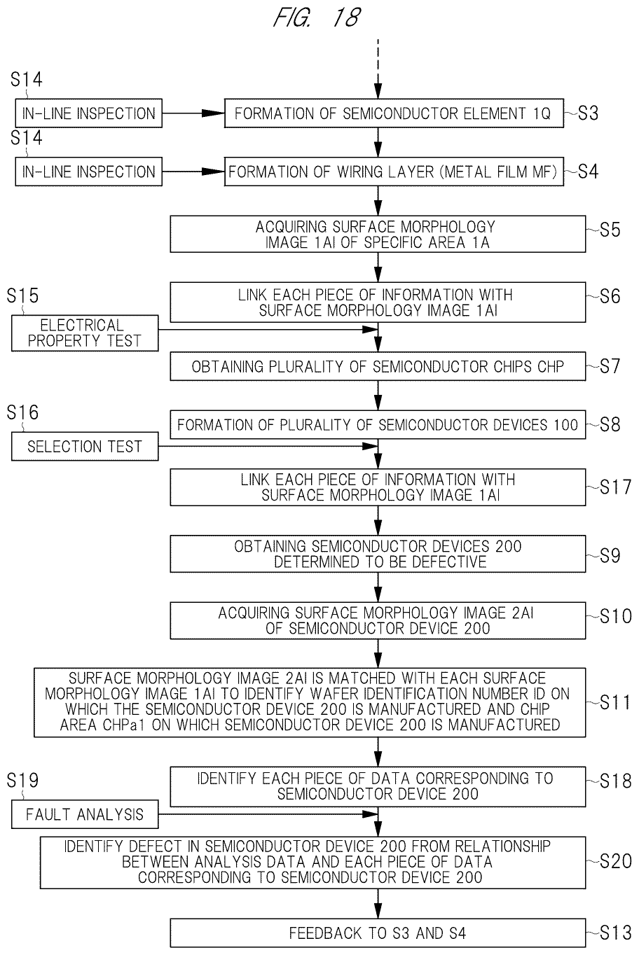

A method of manufacturing semiconductor device 100 and a product history management method for semiconductor device 100 according to a fourth embodiment will be described below with reference to FIG. 16. In the following description, differences from the first embodiment will be mainly described, and descriptions of points that overlap with the first embodiment will be omitted.

In the fourth embodiment, as illustrated in FIG. 16, a geometric pattern 20 is provided on the metal film MF located in the specific area 1A, around the specific area 1A, or both. In FIG. 16, the region of the metal film MF surrounded by the dashed line is illustrated as the specific area 1A. Also, in FIG. 16, in a case is illustrated as an example where a rectangular dummy pattern DP is used as the metal film MF that includes specific area 1A.

Providing the geometric pattern 20 makes it easier to find the specific area 1A when acquiring the surface morphology image 1AI or the surface morphology image 2AI. Therefore, it becomes easier to align the coordinates of the specific area 1A accurately, and the accuracy of matching the surface morphology image 1AI with the surface morphology image 2AI can be improved. Shape data of the geometric pattern 20 is stored in the memory device MD as information related to the position information of the specific area 1A in the chip area CHPa.

As the geometric pattern 20, “Pattern 1” to “Pattern 4” illustrated in FIG. 16 are exemplified. In “Pattern 1”, a plurality of projections and recesses are provided as the geometric pattern 20 on at least one of the four sides of the metal film MF in plan view. In “Pattern 2”, three two-dimensional code patterns are provided as the geometric pattern 20 on the metal film MF. In the case of “Pattern 2”, the area surrounded by the three geometric patterns 20 can be recognized as the specific area 1A. In “Pattern 3” and “Pattern 4”, a slit or slits are provided as the geometric pattern 20 in the metal film MF.

The geometric pattern 20 is not limited to the shapes of “Pattern 1” to “Pattern 4”, and may be another pattern as long as the shape makes it easy to find the specific area 1A.

The technique disclosed in the fourth embodiment can be applied in combination with the techniques disclosed in the second embodiment and the third embodiment.

### Fifth Embodiment

A method of manufacturing semiconductor device 100 and a product history management method for semiconductor device 100 according to a fifth embodiment will be described below with reference to FIG. 17. In the following description, differences from the first embodiment will be mainly described, and descriptions of points that overlap with the first embodiment will be omitted.

In the fifth embodiment, as illustrated in FIG. 17, a plurality of specific areas 1A is provided in the chip area CHPa. In Step S5, the surface morphology image 1AI is acquired for each of the plurality of specific areas.

In Step S10, a plurality of surface morphology image 2AI corresponding to the plurality of specific areas 1A is acquired.

In Step S11, the plurality of surface morphology images 2AI is matched with the plurality of surface morphology images 1AI for each of the plurality of chip areas CHPa stored in the memory device MD.

If only one surface morphology image 1AI of one specific area 1A is acquired for one chip area CHPa, and the corresponding part of the specific area 1A of the semiconductor device 200 determined to be defective is damaged or deformed, it becomes difficult to acquire the surface morphology image 2AI. For example, during the use of the semiconductor device 100, a high electric field may concentrate on a part of the source wiring SW, causing that part of the source wiring SW to be damaged or deformed.

If the plurality of surface morphology images 1AI of the plurality of specific areas 1A is acquired for one chip area CHPa, even if it becomes difficult to acquire the surface morphology image 2AI for a certain position, the surface morphology image 2AI can be acquired for another position. Therefore, according to the fifth embodiment, it becomes easy to eliminate the risk of being unable to match the surface morphology image 1AI with the surface morphology image 2AI.

The technique disclosed in the fifth embodiment can be applied in combination with the techniques disclosed in the second to fourth embodiments.

### Sixth Embodiment

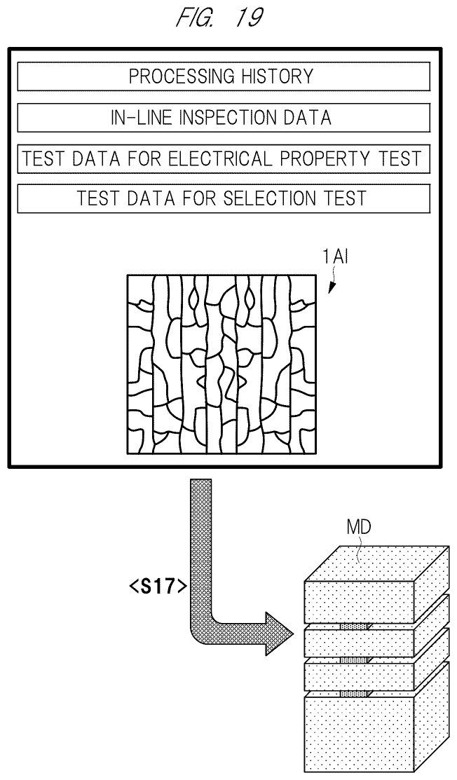

A method of manufacturing semiconductor device 100 and a product history management method for semiconductor device 100 according to a sixth embodiment will be described below with reference to FIG. 18. In the following description, differences from the first embodiment will be mainly described, and descriptions of points that overlap with the first embodiment will be omitted.

In the first embodiment, the relationship between the crystal defects 10 and the defect of the semiconductor device 200 has been described. However, the identification or estimation of the defect of the semiconductor device 200 is not limited to the relationship with the crystal defects 10. In the sixth embodiment, in the process of manufacturing the semiconductor device 100 from the wafer WF, an in-line inspection, an electrical property test, and a selection test are performed, and the acquired inspection data or test data is used to identify defects in the semiconductor device 200.

The product history management method for semiconductor device 100 includes Step S14 to Step S20 illustrated in FIG. 18. The method of manufacturing the semiconductor device 100 includes Step S14 to Step S17 illustrated in FIG. 18, which are part of the product history management method for semiconductor device 100.

As illustrated in FIG. 18, while Step S3 and Step S4 are being performed, the in-line inspection is appropriately performed (Step S14). The in-line inspection includes, for example, one or more of foreign matter inspection, defect inspection, dimensional inspection, overlay inspection, and appearance inspection. Before performing Step S7, the electrical property test is performed on the semiconductor elements 1Q for each of the plurality of chip areas CHPa (Step S15). Also, before performing Step S9, the selection test is performed for selecting the reliability of each of the semiconductor devices 100 (Step S16). The selection test is, for example, a burn-in test.

As described above, the processing histories included in the manufacturing process of the semiconductor element 10 in Step S3 and the manufacturing process of the metal film MF in Step S4 have been stored in the memory device MD.

In Step S17, as illustrated in FIG. 19, the processing histories, the inspection data from the in-line inspection, the test data from the electrical property test, the test data from the selection test, and the surface morphology image 1AI for each of the plurality chip areas CHPa are linked together and stored in the memory device MD.

For example, assume that foreign matter is detected in a certain chip area CHPa when the foreign matter inspection is performed as the in-line inspection. At this point, it is possible to refer to the processing histories and review the manufacturing conditions of the manufacturing step where foreign matter was generated. However, not all foreign matter directly is linked to defects, and some foreign matter may exist that does not result in defects even if left unaddressed. Therefore, if there is no effect on the electrical property of the semiconductor element 10 and the reliability of the semiconductor device 100, it may be determined that the foreign matter may be left as it is.

However, there is also a possibility that the semiconductor device 100 may become defective for some reason during the use thereof, and a fault analysis may reveal that the neglected foreign matter was the cause of the defect. Accordingly, to quickly perform traceability on the semiconductor device 100 having potential defect factors and identify the cause of the defect, the processing histories, each inspection data, and each test data are linked to the surface morphology image 1AI.

Thereafter, Step S9 and Step S10 are performed, and in Step S11, the position of the chip area CHPa1 in which the semiconductor device 200 is manufactured is identified. In Step S18, by having performed Step S17, the processing histories corresponding to the semiconductor device 200 can be identified, and one or more of the inspection data of the in-line inspection, the test data of the electrical property test, and the test data of the selection test corresponding to the semiconductor device 200 can be identified.

For example, if the chip area CHPa1 in which the semiconductor device 200 was manufactured was the chip area CHPa in which foreign matter that would not cause any problems if left as it is was detected during the foreign matter inspection, it can be expected that the foreign matter may have been the cause of the defect.

In Step S19, a fault analysis is performed on the semiconductor device 200. The fault analysis includes one or more of an optical emission analysis, an OBIRCH analysis, a DLS analysis, an IDDQ analysis, a heat generation analysis, a nanoprober analysis, and an EBAC analysis.

In Step S20, from the relationship between the analysis data of the fault analysis and one or more of the inspection data of the in-line inspection, the test data of the electrical property test, and the test data of the selection test corresponding to the semiconductor device 200, the cause of the defect of the semiconductor 200 can be identified.

If the inspection data of the in-line inspection, the test data of the electrical property test, and the test data of the selection test corresponding to the semiconductor device 200 are identified in S18, Step an appropriate analysis can be prioritized of the fault analysis performed in Step S19. For example, in the case of a semiconductor device 200 that has a history of foreign matter being detected in the foreign matter inspection and no abnormalities being detected in the dimensional inspection, it can be predicted that the defect is likely to be caused by the detected foreign matter. Therefore, a fault analysis suitable for detecting a predicted defect can be prioritized.

Accordingly, also in the sixth embodiment, the cause of a defect in a semiconductor device 200 can be identified at an early stage and feedback to the manufacturing method of the semiconductor device 100 can be performed at an early stage. Accordingly, this makes it possible to supply highly reliable semiconductor devices 100 after feedback, improve yield, and suppress the outflow of defective products to the market.

For example, if foreign matter detected during the foreign matter inspection is identified as the cause of a defect, measures can be taken to review the manufacturing step immediately before the foreign matter was generated by referring to the processing histories. Alternatively, measures can be taken such as not commercializing the chip area CHPa1.

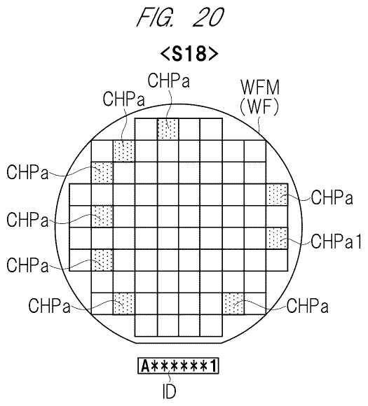

Additionally, as illustrated in FIG. 20, in Step S18, there may be other chip areas CHPa with similar data to the inspection data from the in-line inspection, the test data from the electrical property test, and the test data from the selection test corresponding to the semiconductor device 200 (chip area CHPa1). In that case, it can be estimated that, in the semiconductor devices 100 manufactured from the corresponding chip areas CHPa, the same defect as in the semiconductor device 200 is highly likely to occur. Therefore, the corresponding chip area CHPa may be matched on the wafer map WFM, and the same feedback as in Step S12 may be performed for the corresponding chip area CHPa.

Further, the technique of the sixth embodiment can be used particularly effectively when the cause of the defect in the first embodiment is not the crystal defect 10. For example, by matching the position of the chip area CHPa1 identified in Step S11 with the position information of the crystal defects 10 on the wafer map WFM, and if the crystal defect 10 is not present in the chip area CHPa1, it can be determined that the defect has occurred due to a cause other than the crystal defect 10. In such a case, the cause of the defect can be identified by using the technique of the sixth embodiment.

The technique disclosed in the sixth embodiment can be applied in combination with the techniques disclosed in the second to the fourth embodiments.

In the foregoing, the invention made by the inventors of the present application has been concretely described on the basis of the embodiments. However, it is needless to say that the present invention is not limited to the foregoing embodiments, and various modifications and alterations can be made within the scope of the present invention.

What is claimed is:

1. A method of manufacturing a semiconductor device, comprising:
(a) assigning a wafer identification number to a wafer made of silicon carbide;
(b) partitioning the wafer into a plurality of chip areas arranged in a matrix and generating a wafer map;
(c) inspecting the wafer for a crystal defect present therein;
(d) storing position information of the crystal defect on the wafer map in a memory device by mapping a position of the crystal defect;
(e) forming a semiconductor element in each of the plurality of chip areas;
(f) forming a metal film in a wiring layer located above the semiconductor element in each of the plurality of chip areas;
(g) acquiring a first surface morphology image of a specific area of the metal film in each of the plurality of chip areas; and
(h) linking the position information of the crystal defect on the wafer map, the wafer identification number, position information of the plurality of chip areas, position information of the specific area in the chip area, and the first surface morphology image for each of the plurality of chip areas, and storing them in the memory device.

2. The method of manufacturing the semiconductor device according to claim 1,
wherein the metal film is a film containing aluminum as a main component.

3. The method of manufacturing the semiconductor device according to claim 1, further comprising
(i) forming a protective film on a portion of the metal film so as to cover the specific area,
wherein, in the (g), the first surface morphology image is acquired via the protective film.

4. The method of manufacturing the semiconductor device according to claim 1,
wherein the planar size of the specific area is 50 μm×50 μm or more and 200 μm×200 μm or less.

5. The method of manufacturing the semiconductor device according to claim 1,
wherein the position information of the crystal defect stored in the memory device in the (d) is set as first position information of the crystal defect,
wherein the (e) includes
(e1) performing a heat treatment on the wafer,
(e2), after the (e1), re-inspecting the wafer for a crystal defect present therein, and
(e3), after the (e2), storing second position information of the crystal defect on the wafer map in the memory device by mapping the position of the crystal defect again.

6. The method of manufacturing the semiconductor device according to claim 1,
wherein, in the (g), a plurality of first feature amounts of the first surface morphology image is extracted, and
wherein, in the (h), the plurality of first feature amounts is stored in the memory device as information related to the first surface morphology image.

7. The method of manufacturing the semiconductor device according to claim 1,
a geometric pattern is provided on the metal film located in the specific area, around the specific area, or both.

8. The method of manufacturing the semiconductor device according to claim 1,
wherein a plurality of the specific areas is provided in each of the plurality of chip areas,
wherein, in the (g), the first surface morphology image is acquired for each of the plurality of specific areas.

9. The method of manufacturing the semiconductor device according to claim 1,
wherein each of the plurality of chip areas includes
a cell region in which the semiconductor element is formed, and
an outer periphery region surrounding the cell region in plan view, and
wherein the metal film is formed in the cell region and is electrically connected to the semiconductor element.

10. The method of manufacturing the semiconductor device according to claim 1,
wherein each of the plurality of chip areas includes
a cell region in which the semiconductor element is formed, and
an outer periphery region surrounding the cell region in plan view, and
wherein the metal film is formed in the outer periphery region and is electrically insulated from the semiconductor element.

11. The method of manufacturing the semiconductor device according to claim 1, further comprising:
(j) storing, in the memory device, process histories included in a manufacturing process of the semiconductor element in the (e) and a manufacturing process of the metal film in the (f);
(k) performing in-line inspection during the (e) and during the (f); and
(l) linking the processing histories, inspection data of the in-line inspection, and the first surface morphology image for each of the plurality of chip areas, and storing them in the memory device.

12. The method of manufacturing the semiconductor device according to claim 11,
wherein the in-line inspection includes at least one of foreign matter inspection, defect inspection, dimensional inspection, overlay inspection, and appearance inspection.

13. The method of manufacturing the semiconductor device according to claim 1, further comprising:
(m) performing an electrical property test on the semiconductor element for each of the plurality of chip areas; and
(n) linking test data of the electrical property test and the first surface morphology image for each of the plurality of chip areas, and storing them in the memory device.

14. The method of manufacturing the semiconductor device according to claim 1, further comprising:
(o) obtaining a plurality of semiconductor chips by dicing the plurality of chip areas of the wafer;
(p) forming a plurality of first semiconductor devices by sealing the plurality of semiconductor chips with a sealing resin;
(q) performing a selection test for selecting reliability of each of the plurality of first semiconductor devices; and
(r) linking test data of the selection test and the first surface morphology image for each of the plurality of chip areas, and storing them in the memory device.

15. A product history management method for semiconductor device, comprising:
(a) assigning a wafer identification number to a wafer made of silicon carbide;
(b) partitioning the wafer into a plurality of chip areas arranged in a matrix and generating a wafer map;
(c) inspecting the wafer for a crystal defect present therein;
(d) storing position information of the crystal defect on the wafer map in a memory device by mapping a position of the crystal defect;
(e) forming a semiconductor element in each of the plurality of chip areas;
(f) forming a metal film in a wiring layer located above the semiconductor element in each of the plurality of chip areas;
(g) acquiring a first surface morphology image of a specific area of the metal film in each of the plurality of chip areas;
(h) linking the wafer identification number, the position information of the crystal defect on the wafer map, position information of the plurality of chip areas, position information of the specific area in the chip area, and the first surface morphology image for each of the plurality of chip areas, and storing them in the memory device;
(i) obtaining a plurality of semiconductor chips by dicing the plurality of chip areas of the wafer;
(j) forming a plurality of first semiconductor devices by sealing the plurality of semiconductor chips with a sealing resin;
(k) obtaining a second semiconductor device determined to be defective;
(l) opening the sealing resin of the second semiconductor device and acquiring a second surface morphology image of a portion of the metal film provided on the second semiconductor device that corresponds to the specific area; and
(m) identifying the wafer identification number of the wafer on which the second semiconductor device is manufactured and a position of the chip area on which the second semiconductor device is manufactured by matching the second surface morphology image with the first surface morphology image for each of the plurality of chip areas stored in the memory device,
wherein the position of the chip area identified in the (m) is matched with the position information of the crystal defect on the wafer map, and if the crystal defect is present in the chip area identified in the (m), it can be expected that a defect in the second semiconductor device is caused by the crystal defect.

16. The product history management method for semiconductor device according to claim 15, further comprising:
(n) storing, in the memory device, process histories included in a manufacturing process of the semiconductor element in the (e) and a manufacturing process of the metal film in the (f);
(o) performing in-line inspection during the (e) and during the (f);
(p) performing an electrical property test on the semiconductor element;
(q), after the (j), performing a selection test for selecting reliability of each of the plurality of first semiconductor devices; and
(r) linking the processing histories, inspection data of the in-line inspection, test data of the electrical property test, test data of the selection test, and the first surface morphology image for each of the plurality of chip areas, and storing them in the memory device,
wherein, by identifying the position of the chip area on which the second semiconductor device is manufactured in the (m), the processing histories corresponding to the second semiconductor device is identified, and one or more of the inspection data of the in-line inspection, the test data of the electrical property test, and the test data of the selection test corresponding to the second semiconductor device are identified.

17. The product history management method for semiconductor device according to claim 16, further comprising
(s) performing a fault analysis on the second semiconductor device,
wherein a cause of a defect in the second semiconductor device is identified from a relationship between analysis data of the fault analysis and one or more of the inspection data of the in-line inspection, the test data of the electrical property test, and the test data of the screening test corresponding to the second semiconductor device.

18. The product history management method for semiconductor device according to claim 17,
wherein the fault analysis includes one or more of an optical emission analysis, an OBIRCH analysis, a DLS analysis, an IDDQ analysis, a heat generation analysis, a nanoprober analysis, and an EBAC analysis.

19. The product history management method for semiconductor device according to claim 17,
wherein the identified cause of the defect in the second semiconductor device is fed back to the (e) and the (f).

20. The product history management method for semiconductor device according to claim 15,
wherein when the second surface morphology image does not match any of the first surface morphology images for each of the plurality of chip areas stored in the memory device, the second semiconductor device is identified as a counterfeit product.
